(19) United States
(12) Patent Application Publication
(10) Pub. No.: US 2026/0235397 A1
(43) Pub. Date: Aug. 13, 2026

(54) HEIGHT MEASUREMENT ERROR DETERMINATION

(71) Applicant: ASML NETHERLANDS B.V., Veldhoven (NL)

(72) Inventor: Attaallah ALMASI, Utrecht (NL)

(73) Assignee: ASML NETHERLANDS B.V., Veldhoven (NL)

(21) Appl. No.: 19/161,098

(22) PCT Filed: Feb. 29, 2024
(86) PCT No.: PCT/EP2024/055230

§ 371 Date: Aug. 29, 2025

(30) Foreign Application Priority Data
Mar. 30, 2023 (EP) 23165575.4

(51) Int. Cl. G01B 11/06; G03F 7/00

(52) U.S. Cl. CPC G01B 11/0608; G03F 7/70508; G03F 7/7085

(57) ABSTRACT

A method of determining a substrate height measurement error, the method including providing a laser beam that is modulated at a given frequency, the laser beam having a wavelength and a polarization, directing the modulated laser beam onto the substrate at an acute angle relative to a normal extending from the substrate, detecting a position of the modulated laser beam after it has been reflected from the substrate, using detection based upon the frequency of the modulation applied to the laser beam to measure a modulation of the detected position of the modulated laser beam, and determining the height measurement error based upon the measured modulation of the detected position of the modulated laser beam, wherein the wavelength or the polarization is modulated.

### CROSS-REFERENCE TO RELATED APPLICATION

The application claims priority of EP Application Serial No. 23165575.4 which was filed on 30 Mar. 2023, and which is incorporated herein in their entirety by reference.

### FIELD

The present disclosure relates to determining a substrate height measurement error. The substrate height measurement error may be determined in a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask also referred to as a reticle) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Typically, the substrate may include multiple layers comprising one or more materials (each layer having been patterned by a reticle) and each of the layers may comprise multiple repetitions of the same pattern. The patterns of each layer may be arranged as a two-dimensional array. Any and all references to “substrate” are to be understood as comprising a ‘base’ substrate, e.g., a silicon or glass substrate, or any other appropriate base substrate, and any layers provided thereupon, including but not limited to previously exposed and processed patterned layers, and/or photoresist.

Different points across a surface of the substrate may be at different heights, and so lithographic radiation focused on the surface of the substrate at a first point (at a first height) may not be in focus at a second point (at a second height). To maintain focus on the substrate surface, the height of the surface of the substrate is measured and corresponding adjustments of the lithographic apparatus are made.

The height of the surface of the substrate may be measured using a height measurement system. However, it is known that light which is used by a height measurement system to measure the height of the surface of the substrate may penetrate partially into the substrate surface, instead of being reflected solely from the substrate surface. A partial reflection of the light may occur from layers beneath the surface of the substrate. This partial reflection causes a substrate height measurement error.

The substrate height measurement error may be referred to as height process dependency (HPD) or apparent surface depression (ASD).

It may be desirable to provide a system that obviates or mitigates one or more problems associated with the prior art.

### SUMMARY

According to a first aspect of the disclosure, there is provided a method of determining a substrate height measurement error, the method comprising providing a laser beam that is modulated at a given frequency, the laser beam having a wavelength and a polarization, directing the modulated laser beam onto the substrate at an acute angle relative to a normal extending from the substrate, detecting a position of the modulated laser beam after it has been reflected from the substrate, using detection based upon the frequency of the modulation applied to the laser beam to measure a modulation of the detected position of the modulated laser beam, and determining the height measurement error based upon the measured modulation of the detected position of the modulated laser beam, wherein the wavelength or the polarization is modulated.

Advantageously, the method determines a height measurement error in a manner which is different from prior art methods. Advantageously, the method may be performed quickly and may be performed within a lithographic apparatus (e.g., before or during exposure of the substrate).

The height measurement error may be an absolute value which is determined with reference to known refractive indices of layers of the substrate.

The height measurement error may be a relative value which is determined by comparison of the measured modulation of the detected position of the modulated laser beam with measured calibration modulations obtained using a different substrate having a layer structure which corresponds with the layer structure of the substrate being measured.

The height measurement error may be a relative value which is determined by comparison between the measured modulation of the detected position of the modulated laser beam for different measured locations on the substrate.

The detection may measure the modulation of the detected position of the modulated laser beam using a harmonic of the frequency of the modulation applied to the wavelength or to the polarization of the laser beam.

The detection may be lock-in detection which automatically selects between a first harmonic, second harmonic, or other harmonic of the frequency of the modulation based upon amplitudes of those harmonics.

The modulation of the wavelength of the laser beam may be up to 1/100th of the wavelength of the laser beam.

The modulation of the wavelength of the laser beam may be up to 100 pm.

The laser beam may be provided by a single frequency laser.

According to a second aspect of the disclosure, there is provided a method of determining a height of a substrate, the method comprising measuring the height of the substrate, determining a substrate height measurement error using the method of the first aspect of the disclosure, and adjusting the measured height of the substrate using the determined substrate height measurement error.

According to a third aspect of the disclosure, there is provided a substrate height measurement error determination system comprising a projection unit comprising a laser, the projection unit being configured to direct a laser beam emitted by the laser onto a substrate, the laser beam having a wavelength and a polarization, a detection system comprising a detector configured to detect a position of the laser beam after reflection from the substrate, a modulator configured to apply a modulation at a given frequency to the wavelength or to the polarization of the laser beam emitted by the laser, to obtain a modulated laser beam, a lock-in amplifier configured to receive an output from the detection system and, based upon the frequency of the modulation applied to the wavelength or the polarization of the laser beam, to measure a modulation of the detected position of the modulated laser beam, and a processor configured to use the measured modulation of the detected position to determine a substrate height measurement error.

Advantageously, the system of the third aspect determines a height measurement error in a manner which is different from prior art methods. Advantageously, the system allows the height measurement error to be determined quickly. Advantageously, the height measurement error system may be within a lithographic apparatus.

The detector may be a lock-in detector. The modulator and the detector may both be part of a lock-in amplifier.

The lock-in detector may automatically select between a first harmonic, second harmonic, or other harmonic of the frequency of the modulation based upon amplitudes of those harmonics.

The modulator may be configured to modulate the wavelength or the polarization of the laser beam by up to 1/100^{th} of the wavelength of the laser beam.

The modulator may be configured to modulate the wavelength of the laser beam by up to 100 pm.

The laser may be a single frequency laser.

According to a fourth aspect of the disclosure, there is provided a measurement system comprising a substrate height measurement error determination system according to the third aspect, and a substrate height measurement system, wherein the processor is configured to use the determined substrate height measurement error to adjust a measured height of the substrate obtained using the substrate height measurement system.

The detection system may comprise part of the substrate height measurement system.

The projection unit may comprise part of the substrate height measurement system.

According to a fifth aspect of the disclosure there is provided a lithographic apparatus comprising the measurement system of the fourth aspect of the disclosure.

Features of different aspects of the disclosure may be combined together.

### BRIEF DESCRIPTION OF THE DRAWINGS

Embodiments of the disclosure will now be described, by way of example only, with reference to the accompanying drawings, in which:

FIG. 1 schematically depicts a lithographic apparatus which includes a system for determining a substrate height measurement error according to an embodiment of the disclosure; and

FIG. 2 schematically depicts in more detail the system for determining the substrate height measurement error of FIG. 1.

### DETAILED DESCRIPTION

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate.

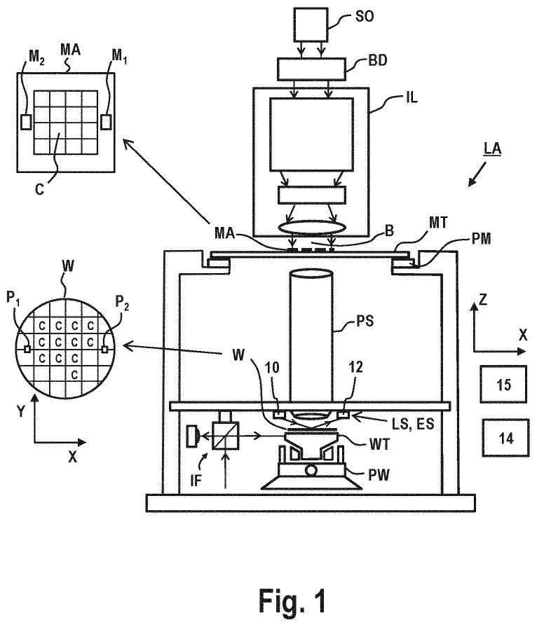

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g., via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT. In such a “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In operation, the radiation beam B is incident on the patterning device, e.g., mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the disclosure, a Cartesian coordinate system is used. The Cartesian coordinate system has three axes, i.e., an x-axis, a y-axis and a z-axis. Each of the three axes is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the disclosure and is used for clarification only. Instead, another coordinate system, such as a cylindrical coordinate system, may be used to clarify the disclosure. The orientation of the Cartesian coordinate system may be different, for example, such that the z-axis has a component along the horizontal plane. In the figures, the height of the substrate W is indicated as the Z-direction.

A height measurement system LS is arranged to measure a topography of a top surface of the substrate W. The height measurement system LS may be referred to as a level sensor, or a topography measurement system. A map of the height (z) of the substrate as a function of position (x, y) on the substrate may be generated from measurements obtained using the height measurement system LS. This height map may subsequently be used to adjust the vertical position of the substrate W, and/or to adjust the projection system PS, during projection of a pattern from the patterning device MA onto the substrate.

The height measurement system LS may be stationary. The substrate table WT and substrate W may be moved in a scanning movement beneath the height measurement system LS. This allows the height measurement system to measure height across a surface of the substrate W and thereby generate a height map.

The height measurement system LS comprises a projection unit 10, a detection system 12, and a processor 15. The projection unit 10 is configured to provide a beam of light which is incident upon the substrate W (including any patterned layers thereon) and is then detected by the detection system 12. A position at which the beam of light is incident at the detection system 12 depends upon the height of the substrate W. This allows the height of the substrate W to be measured. The projection unit 10 comprises a diffraction grating (not depicted), which may be referred to as a projection grating. The detection system 12 comprises a diffraction grating (not depicted) which may be referred to as a detection grating. An image of the projection grating is formed at the detection grating, and a position of this grating image relative to the detection grating provides the height measurement.

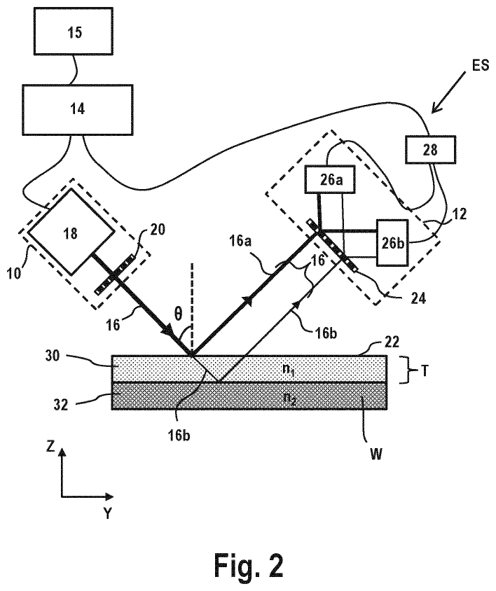

The height measurement system LS may comprise multiple lasers (or other light sources). The height measurement system LS may for example comprise a broadband light source, for example a white light source that emits light across the visible spectrum. The height measurement system may, for example, comprise multiple lasers, which are configured to emit light at different wavelengths. An output from the detection system 12 may be processed by the processor 15 to obtain a measured height of the substrate W. The measured height of the substrate may include a measurement error arising from the reflection of light from multiple layers of the substrate (as explained further below in connection with FIG. 2).

The lithographic apparatus further comprises a height measurement error determination system ES. The height measurement error determination system ES uses some of the same components as the height measurement system LS, and these are indicated as common components in FIG. 1.

The height measurement error determination system ES comprises at least one single frequency laser 18. The single frequency laser may for example have a bandwidth of 10 MHz or less, e.g., a bandwidth of around 1 MHz. The laser 18 may form part of the projection unit 10. A position of a reflection of a laser beam 16, provided by the projection unit 10, is detected by the detection system 12. A signal module 14 is arranged, which comprises a modulation unit (or modulator) and a lock-in amplifier. The modulator is configured to modulate the wavelength and/or the polarization of the laser beam 16 that is emitted by the projection unit 10. The lock-in amplifier is configured to receive an output signal from the detection system 12. The detected position of the reflected laser beam is modulated due to the wavelength or polarization modulation of the laser beam. The lock-in amplifier provides an output, which is a measurement of the detected position modulation. The processor 15 uses the output from the lock-in amplifier to determine a height measurement error. The height measurement error may be applied to the measured height of the substrate. The height measurement error may be referred to as height process dependency (HPD).

The height measurement error determination system ES is depicted in more detail in FIG. 2. As noted above, some components of the height measurement error determination system ES may also form part of the height measurement system LS. The projection unit 10 comprises a single frequency laser 18 and a diffraction grating 20. The diffraction grating 20, which is referred to as the projection grating 20 applies a periodic structure to the laser beam 16. The laser beam 16 is incident upon the substrate W. The laser beam 16 subtends an acute angle θ with respect to a normal, which extends from the substrate W (in other words, with respect to the Z-direction).

The laser 18 is configured to emit the laser beam 16 with a bandwidth of less than 2 nm, and may be referred to as a narrowband laser. The modulator of the signal module 14 may apply a modulation to the wavelength of the laser beam 16 emitted by the laser 18. The modulator may, for example, vary the wavelength of the laser beam 16 by about 1 pm. The modulator may vary the wavelength of the laser beam by up to 10 pm, or up to 50 pm. The modulator may vary the wavelength by more than this, for example up to 100 pm. However, if a larger wavelength modulation such as 100 pm is used, the output from the lock-in amplifier may no longer be in a linear regime (this will depend upon the structure of the substrate).

In general, the modulation of the wavelength may be up 1/100^{th} of a central wavelength of the laser beam 16.

Light emitted by a laser is typically polarized light. Though the light source arranged in the projection unit 10 (or the unit itself) may be provided with a polarizer (not shown in FIG. 2) to provide a light beam 16 with the desired polarization. An analyzing polarizing element may be arranged at the detection system 12 (not illustrated in FIG. 2).

The modulator of the signal module 14 may apply a modulation to the polarization of the laser beam 16 emitted by the laser 18. For example, a polarization modulator may be arranged to interact with the laser beam 16 within the projection unit 10. The polarization modulator may be a liquid crystal based modulator (or polarization rotator) or an electro-optical element that controls the polarization state of the light beam 16 by an externally applied voltage. By means of the polarization module, the polarization state of the light beam 16 can be modulated at a predefined frequency.

In general, a substrate will comprise many patterned layers. However, for simplicity of description, the substrate W depicted in FIG. 2 has only two layers, a lower layer of silicon 32 (which may be referred to as a ‘base’ substrate) and an upper layer of photoresist 30 (which may be referred to as resist). A main portion 16a of the laser beam 16 is reflected from an upper surface 22 of the resist 30. The reflected main portion of the laser beam 16a is reflected towards the detection system 12.

The detection system 12 comprises a diffraction grating 24 and a pair of detectors 26a,b. The diffraction grating 24 may be referred to as the detection grating 24. The reflected main portion of the laser beam 16a forms an image of the projection grating 20 at the detection grating 24. The detection grating 24 may have a periodicity, which corresponds with a periodicity of a grating image formed by the reflected main portion of the laser beam 16a. The position of this grating image will depend upon the height of the upper surface 22 of the resist 30. The detection grating 24 directs laser light towards the first and second detectors 26a,b. The proportion of laser light received by each detector 26a,b depends upon the position of the grating image with respect to the detection grating 24. Thus, the signals output from the detectors 26a,b depend upon the height of the upper surface 22 of the resist 30. A differential amplifier 28 may be used to determine a difference between the signals output from the detectors 26a,b. An output from the differential amplifier 28 is provided to the signal module 14. Other position detection systems for detecting the position of a reflected laser beam may be used.

The projection unit 10 and the detection system 12 may include further optical elements, such as lenses and/or mirrors (not depicted), along the path of the laser beam 16 (e.g., between the projection grating 20 and the detection grating 24).

As noted above, the main portion of the laser beam 16a is reflected from the upper surface 22 of the resist 30. However, the resist 30 is not a perfect reflector, and as a result a portion 16b of the laser beam 16 passes through the resist. This secondary laser beam portion 16b is reflected from an interface between the resist 30 and the silicon substrate 32. The secondary laser beam portion 16b is a relatively small proportion of the incident laser beam 16, for example 10% or less of the incident laser beam (e.g., 1% or less of the incident laser beam). This is schematically depicted by the secondary laser beam portion 16b being a line which is less thick than the main laser beam portion 16a.

The secondary laser beam portion 16b also forms an image of the projection grating 20 at the detector grating 24. However, this grating image is formed at a different, lower, position than the grating image formed by the main laser beam portion 16a. As can be seen from FIG. 2, the position of the detector grating image provided by the secondary laser beam portion 16b is determined by the height of the silicon substrate 32. A height offset between the position of the grating image provided by the main laser beam portion 16a and the position of the grating image provided by the secondary laser beam portion 16b will depend upon the thickness T of the resist.

The grating image formed by the secondary laser beam portion 16b introduces a measurement error into the signals output from the detectors 26a,b. The signals output from the detectors 26a,b will indicate that the height of the upper surface 22 of the resist is below the actual height of the upper surface of the resist. The height measurement error determination system ES determines this height measurement error. The height measurement error may be used to adjust a height measurement obtained using the height measurement system LS (see FIG. 1).

The height measurement error, which is determined by the system ES, may be an absolute measurement, i.e., a value that indicates an offset between the measured height of the upper surface 22 of the resist 30 and the actual height of the upper surface of the resist. The height measurement error may be a relative value, e.g., a value which indicates whether the height measurement error at a given area of the substrate is greater than or less than the height measurement error at a different area of the substrate.

The measurement obtained by the height measurement error determination system ES is now explained in more detail with reference to FIG. 2. The optical path difference L between the main laser beam portion 16a and the secondary laser beam portion 16b may be expressed as:

$$L ( θ ) = 2 T \sqrt{{n}_{1}^{2} - {sin}^{2} ( θ )} \qquad ( 1 )$$

The reflected laser beam 16 considered as a single beam has a complex amplitude:

$${E}_{r} = A + a exp ( - i 2 π \frac{L ( θ )}{λ} ) \qquad ( 2 )$$

where A is the amplitude of the main laser beam portion 16a and a is the amplitude of the secondary laser beam portion 16b. It can be assumed that n₁>>1 and n₁≈n₂ (n₁ is the refractive index of the resist 30 and n₂ is the refractive index of the silicon substrate 32). Consequently, it can be assumed that the reflection 16b from the silicon substrate 32 is weak compared to the reflection 16a from the resist 30. When a<<A the phase of the reflected laser beam 16 is:

$$φ ( θ ) \approx \frac{a}{A} sin ( 2 π \frac{L ( θ )}{λ} ) \qquad ( 3 )$$

The height measurement error HPD caused by the secondary laser beam portion 16b, with an assumption that n²>>sin(θ), may be expressed as:

$$HPD = \frac{λ}{4 π sin ( θ )} \frac{d φ}{d θ} \approx \frac{T}{{n}_{2}} \frac{a}{A} cos ( 4 π \frac{{n}_{2} T}{λ} ) cos ( θ ) \qquad ( 4 )$$

Equation 4 includes the following term:

$$cos ( 4 π \frac{{n}_{2} T}{λ} ) \qquad ( 5 )$$

which indicates that the measurement error HPD will oscillate as a function of the wavelength of the laser beam 16. Embodiments of the disclosure obtain information regarding the height measurement error HPD by applying a modulation to the wavelength of the laser beam 16.

The modulator of the signal module 14 provides a modulation signal that controls the operation of the laser 18 such that the central wavelength of the laser beam 16 is modulated. The modulation is at a given frequency (e.g., selected by a user or automatically selected by the lock-in amplifier). This causes a modulation of the position of the reflected laser beam 16 as detected by the detectors 26a,b.

The lock-in amplifier of the signal module 14 measures a modulation of the detected position of the laser beam 16 using the frequency of the modulation applied to the laser beam. The lock-in amplifier is configured to identify a harmonic (e.g., a first harmonic) of the signal output from the operational amplifier 28 (or other output signal if a different position detection system is used). The lock-in amplifier identifies the harmonic as a component of the output signal, which has a frequency that is a harmonic of the modulation applied to the laser 18. The lock-in amplifier of the signal module 14 provides an output signal having an amplitude, which indicates the amplitude of the detected harmonic. The processor 15 receives the output signal from the lock-in amplifier. The processor 15 uses the output signal to determine the height measurement error. As noted above, the height measurement error may be an absolute value or may be a relative value. The height measurement error may be used to adjust a height measurement obtained by the height measurement system LS.

In some instances, the first harmonic of the signal received by the lock-in amplifier may have a lower amplitude than for example the second harmonic. The relative amplitudes of different harmonics will depend upon the refractive index and thickness of the layer of resist 30 in the scenario depicted in FIG. 2. The lock-in amplifier may be configured to automatically select a harmonic which provides the greatest signal amplitude. In other scenarios (not depicted) in which the substrate is provided with more layers, the relative amplitudes of different harmonics will depend upon the refractive index and thickness of each layer. Again, the lock-in amplifier may be configured to automatically select a harmonic which provides the greatest signal amplitude. For example, for some substrates the first harmonic may provide a strong signal that can be used to determine the height measurement error. For other substrates, the second harmonic may provide a strong signal that can be used to determine the height measurement error. Other harmonics may be used. In general, lock-in detection automatically selects between a first harmonic, second harmonic, or other harmonic of the frequency of the modulation based upon amplitudes of those harmonics.

Similar as controlling the (central) wavelength of the laser 18 by a modulation signal, the polarization of the light beam (laser beam) 16 can be controlled by a modulation signal provided to a polarization module. By the polarization module the polarization state of the laser beam 16 is altered. That is, the polarization is rotated by several degrees: about 1° or more, about 5° or more, about 10° or more, 15° or more, 30° or more, 45° or more, and may depend on the frequency response of the polarization module. In this case, the polarization of the incident light is modulated to obtain a signal that has a correlation with a product structure. As the product structure has impact on the intensity of the reflected light from it, the polarization-modulated light can be used to reduce the effect of the product structure to the detected light.

In general, lock-in detection is used to measure a modulation of the detected position of the modulated wavelength laser beam (as detected by the detectors 26a,b). The lock-in detection is achieved by modulating the laser beam at a given frequency, and then using that frequency to identify the modulation of the detected position. The modulation of the laser beam, and the lock-in detection, may both be performed by the signal module 14.

In an embodiment, a broadband light source (or other light source) of the height measurement system LS may be provided adjacent to the laser 18 of the height measurement error determination system ES. Where this is the case, the projection grating 20, detection grating 24, detector 26 may be common between the two systems. The systems LS, ES may operate simultaneously. That is, the height measurement system LS may measure a height map for a substrate W, and the height measurement error determination system ES may at the same time determine a height measurement error. The height measurement error determination system ES may provide a height measurement error map.

In the scenario depicted in FIG. 2, the adjustment that is determined may be an absolute measurement of the height measurement error HPD, i.e., a value which indicates an offset between the measured height of the upper surface 22 of the resist 30 and the actual height of the upper surface of the resist. Referring to Equation (5), the refractive index n₁ of the resist 30 is known, the angle of incidence θ of the laser beam 16 is known, and the wavelength λ of the laser beam is known. The relative amplitudes a, A of the first and second laser beam portions 16a,b may be measured during a calibration. The height measurement error HPD can therefore be treated as an absolute value which depends upon the only unknown T. The height measurement error HPD may be subtracted from a measured height of the upper surface 22 of the resist in order to obtain a corrected height.

The above is an example for a substrate having a relatively simple structure. In practice the substrate may comprise more than two layers, e.g., five layers or more, ten layers or more, etc. Where this is the case, it may not be possible to directly obtain an absolute value for the height measurement error HPD. As may be understood from Equation (4), the height measurement error HPD will depend upon the thickness and the refractive index of each layer of a many layered substrate. Since the height measurement error HPD depends upon many different parameters, the height measurement error HPD may not directly provide an absolute value which can be subtracted from a measured height in order to obtain a corrected height. However, in such a scenario, embodiments of the disclosure may still provide useful information. In particular, a relative measurement of the height measurement error HPD may be used to adjust the measured height. For example, a height measurement error HPD may be converted to an absolute value for height correction via comparison with a previous calibration measurement. For example, a height adjustment may be determined for a substrate having a given layer structure (e.g., by comparing a broadband level sensor LS output with an output obtained using an air gauge). An embodiment of the disclosure may determine the height measurement error HPD for that calibrated substrate. This provides a calibration of the height measurement error HPD with respect to a difference between the broadband level sensor LS output and the actual substrate height. The height measurement error HPD for another substrate with the same layer structure may subsequently be measured as part of a lithographic exposure. The height measurement error HPD may be compared with the height measurement error HPD obtained using the calibrated substrate. The result of the comparison may be used to obtain a height adjustment. The height adjustment can be used to obtain a corrected height for the substrate that is being exposed.

In another embodiment, the height measurement error may be used as one of a plurality of error measurements which are used to adjust a measured substrate height.

Typically, more than 200 dies are exposed on a substrate, and in some cases more than 600 dies are exposed on a substrate. Each of the dies has been exposed using the same series of patterning device exposures and has experienced the same processing. Thus, each of the dies should have the same properties, including the same height measurement error. In practice, the height measurement error may vary across a substrate. This may occur for example due to the effect of processing of substrate layers. In one example, metal may be deposited into structures formed in the substrate, and excess metal may be removed from the substrate using polishing. The polishing may for example remove slightly more material from one side of the substrate compared with an opposite side of the substrate (e.g., there may be a gradient of metal thickness across the substrate). Embodiments of the disclosure may provide as an output height measurement error values which vary gradually across the surface of a substrate. The height measurement error values may be used to adjust an expected height measurement error for the substrate. This adjusted expected height measurement error may be used as a height adjustment which is applied to the measured height of the substrate.

Calibration of the height measurement error determination system according to embodiments of the disclosure may comprise determining relative amplitudes of the primary reflective beam portion 16a and the secondary reflective beam portion 16b. The calibration may comprise directing the laser beam 16 at a substrate and changing the (central) wavelength of the laser beam 16 by a few nanometers, e.g., 10 nm. Similarly, the calibration may comprise directing the laser beam 16 at a substrate and changing the polarization of the laser beam 16 by a several degrees: about 1° or more, about 5° or more, about 10° or more, 15° or more, 30° or more, 45° or more, and may depend on the frequency response of the polarization module. The calibration may be performed at a single position on the substrate. The calibration may be performed for multiple positions for a given die on the substrate. The calibration may be performed for each measurement location on the substrate.

An initial calibration of the height measurement error determination system may be performed. This initial calibration, which may be referred to as an electronic calibration, is intended to determine gain of the system. For this initial calibration, a substrate W having a known structure is used. The substrate W may for example be a substrate, which has not yet received any device patterns, that includes alignment marks (the properties of such substrates are well known). The substrate W may comprise two layers. The laser beam 16 is directed onto the substrate W and is detected. An output is provided from the lock-in amplifier of the signal module 14. The processor 15 compares the output from the lock-in amplifier with the known thickness of the upper layer of the substrate. This provides a gain value, i.e., a factor that can be used to multiply signals output from the system during subsequent use. The initial calibration may use more than one measurement.

The output of the detector 26a,b will be received by the lock-in input channels. A lock-in phase lock loop will lock on the signal and extract the amplitude and the phase of the reflected light 16a,b. Two signals are available, the amplitude of the first harmonic will have a strong correlation with the product (layer) structure. The original height map from the level sensor LS (the main signal) and the output of error determination system ES (HPD signal). There are quiet a few methods to clean the correlated part of main signal using the HPD signal as a reference or as second detector signal. These methods may need a calibration. It would be a matter of a solving a set of linear equations to reduce the HPD contribution to the error. In the same manner, the output of the level sensor LS and error determination system ES as two detectors measuring these two events producing a mixed signal. This is also known as the “cocktail party” problem. There are a few methods to unmix these two signals, without needing specific calibration. An example of such a technique is known as blind signal separation (BSS) or blind source separation.

In order to cover the surface of the substrate W effectively, embodiments of the disclosure may be configured to project an array of laser beams 16 onto the surface of the substrate W. This provides an array of measurement areas on the substrate, covering a larger measurement range.

Described embodiments of the disclosure comprise a height measurement system LS and a separate height measurement error determination system ES. However, in an embodiment a single system may be used. That is, the height measurement error determination system ES may determine a height measurement error and may also provide a substrate height measurement.

Embodiments of the invention are described as comprising a single frequency laser having a bandwidth of 10 MHz or less, e.g., a bandwidth of around 1 MHz. Embodiments of the invention may comprise a single frequency laser having a bandwidth of up to 20 MHz. Such an embodiment may provide a useful height measurement error. However, the dynamic range of such an embodiment will be less than for a single frequency laser having a narrower bandwidth.

While the methods described herein have been described in relation to a substrate W that has, or will be, exposed to lithographic radiation (i.e., the radiation beam B), as will be clear to the skilled person, the methods (and corresponding apparatus) may beneficially be adapted for use with substrates that are not exposed to lithographic radiation.

In described embodiments of the invention, wavelength/polarization modulation and harmonic detection are performed by a lock-in amplifier system. However, any suitable apparatus may be used to apply the wavelength modulation, and any suitable apparatus may be used to detect a harmonic of the applied modulation. In general, any of homodyne detection, heterodyne detection and quadrature detection may be used. These are examples of lock-in detection. Detection may use hardware or software.

The height measurement system and the height measurement error determination system may be collectively referred to as a measurement system.

Embodiments of the disclosure may form part of a lithographic apparatus (e.g., as depicted) or a metrology apparatus. Embodiments of the disclosure may form part of a lithographic tool. Further examples of lithographic tools are mentioned further below.

Likewise, while the methods described herein have been described in relation to DUV lithographic radiation, as will be clear to the skilled person, the methods (and corresponding apparatus) may be beneficially adapted for use with EUV lithographic radiation (and corresponding apparatus).

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the disclosure in the context of a lithographic apparatus, embodiments of the disclosure may be used in other apparatus. Embodiments of the disclosure may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the disclosure in the context of optical lithography, it will be appreciated that the disclosure, where the context allows, is not limited to optical lithography and may be used in other applications, for example imprint lithography.

Where the context allows, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Aspect of the invention are set out in the clauses below.

1. A method of determining a substrate height measurement error, the method comprising: providing a laser beam with a wavelength or polarization that is modulated at a given frequency; directing the modulated wavelength laser beam onto the substrate at an acute angle relative to a normal extending from the substrate;
detecting a position of the modulated laser beam after it has been reflected from the substrate;
using detection based upon the frequency of the modulation applied to the wavelength or polarization of the laser beam to measure a modulation of the detected position of the modulated laser beam; and
determining the height measurement error based upon the measured modulation of the detected position of the modulated laser beam.

2. A method of determining a substrate height measurement error, the method comprising:
providing a laser beam that is modulated at a given frequency, the laser beam having a wavelength and a polarization;
directing the modulated laser beam onto the substrate at an acute angle relative to a normal extending from the substrate;
detecting a position of the modulated laser beam after it has been reflected from the substrate;
using detection based upon the frequency of the modulation applied to the laser beam to measure a modulation of the detected position of the modulated laser beam; and
determining the height measurement error based upon the measured modulation of the detected position of the modulated laser beam, wherein the wavelength or the polarization is modulated.

3. The method of clause 1 or 2, wherein the height measurement error is an absolute value which is determined with reference to known refractive indices of layers of the substrate.

4. The method of clause 1 or 2, wherein the height measurement error is a relative value which is determined by comparison of the measured modulation of the detected position of the modulated laser beam with measured calibration modulations obtained using a different substrate having a layer structure which corresponds with the layer structure of the substrate being measured.

5. The method of clause 1 or 2, wherein the height measurement error is a relative value which is determined by comparison between the measured modulation of the detected position of the modulated laser beam for different measured locations on the substrate.

6. The method of any preceding clause wherein the detection measures the modulation of the detected position of the modulated laser beam using a harmonic of the frequency of the modulation applied to the wavelength or the polarization of the laser beam.

7. The method clause 6, wherein the detection is lock-in detection which automatically selects between a first harmonic, second harmonic, or other harmonic of the frequency of the modulation based upon amplitudes of those harmonics.

8. The method of any preceding clause, wherein the wavelength is modulated and the modulation of the wavelength of the laser beam is up to 1/100^{th} of the wavelength of the laser beam.

9. The method of any preceding clause, wherein the wavelength is modulated and the modulation of the wavelength of the laser beam is up to 100 pm.

10. The method of any preceding clause, wherein the laser beam is provided by a single frequency laser.

11. A method of determining a height of a substrate, the method comprising measuring the height of the substrate, determining a substrate height measurement error using the method of any preceding claim, and adjusting the measured height of the substrate using the determined substrate height measurement error.

12. A substrate height measurement error determination system comprising:
a projection unit comprising a laser, the projection unit being configured to direct a laser beam emitted by the laser onto a substrate, the laser beam having a wavelength and a polarization;
a detection system comprising a detector configured to detect a position of the laser beam after reflection from the substrate;
a modulator configured to apply a modulation at a given frequency to the wavelength or to the polarization of the laser beam emitted by the laser;
a detector configured to receive an output from the detection system and, based upon the frequency of the modulation applied to the wavelength or to the polarization of the laser beam, to measure a modulation of the detected position of the modulated wavelength laser beam; and
a processor configured to use the measured modulation of the detected position to determine a substrate height measurement error.

13. The substrate height measurement error determination system of clause 12, wherein the modulator and the lock-in amplifier are both part of a signal module.

14. The substrate height measurement error determination system of clause 12, wherein the lock-in amplifier, automatically selects between a first harmonic, second harmonic, or other harmonic of the frequency of the modulation based upon amplitudes of those harmonics.

15. The substrate height measurement error determination system of any of clauses 12 to 14, wherein the wavelength is modulated and the modulator is configured to modulate the wavelength of the laser beam by up to 1/100^{th} of the wavelength of the laser beam.

16. The substrate height measurement error determination system of any of clauses 12 to 15, wherein the wavelength is modulated and the modulator is configured to modulate the wavelength of the laser beam by up to 100 pm.

17. The substrate height measurement error determination system of any of clauses 12 to 16, wherein the laser is a single frequency laser.

18. A measurement system comprising a substrate height measurement error determination system according to any of clauses 12 to 17, and a substrate height measurement system, wherein the processor is configured to use the determined substrate height measurement error to adjust a measured height of the substrate obtained using the substrate height measurement system.

19. The measurement system of clause 18, wherein the detection system comprises part of the substrate height measurement system.

20. The measurement system of clause 18 or clause 19, wherein the projection unit comprises part of the substrate height measurement system.

21. A lithographic apparatus comprising the measurement system of any of clauses 18 to 20.

While specific embodiments of the disclosure have been described above, it will be appreciated that the disclosure may be practiced otherwise than as described. The descriptions above are intended to be illustrative, not limiting. Thus it will be apparent to one skilled in the art that modifications may be made to the disclosure as described without departing from the scope of the claims set out below.

1. A method of determining a substrate height measurement error, the method comprising:
directing a laser beam modulated at a given frequency onto the substrate at an acute angle relative to a normal extending from the substrate, the laser beam having a wavelength and a polarization;
detecting a position of the modulated laser beam after it has been redirected from the substrate;
using detection based upon the frequency of the modulation applied to the laser beam to measure a modulation of the detected position of the modulated laser beam; and
determining the height measurement error based upon the measured modulation of the detected position of the modulated laser beam, wherein the wavelength or the polarization is modulated.

2. The method of claim 1, wherein the height measurement error is an absolute value being determined with reference to known refractive indices of layers of the substrate.

3. The method of claim 1, wherein the height measurement error is a relative value being determined by comparison of the measured modulation of the detected position of the modulated laser beam with measured calibration modulations obtained using a different substrate having a layer structure which corresponds with the layer structure of the substrate being measured.

4. The method of claim 1, wherein the height measurement error is a relative value being determined by comparison between the measured modulation of the detected position of the modulated laser beam for different measured locations on the substrate.

5. The method of claim 1, wherein the detection measures the modulation of the detected position of the modulated laser beam using a harmonic of the frequency of the modulation applied to the wavelength or the polarization of the laser beam.

6. The method of claim 5, wherein the detection is a lock-in detection that automatically selects between a first harmonic, second harmonic, or other harmonic of the frequency of the modulation based upon amplitudes of those harmonics.

7. The method of claim 1, wherein the wavelength is modulated and the modulation of the wavelength of the laser beam is up to 1/100^{th} of the wavelength of the laser beam.

8. The method of claim 1, wherein the wavelength is modulated and the modulation of the wavelength of the laser beam is up to 100 pm.

9. A method of determining a height of a substrate, the method comprising measuring the height of the substrate, determining a substrate height measurement error using the method of claim 1, and adjusting the measured height of the substrate using the determined substrate height measurement error.

10. A substrate height measurement error determination system comprising:
a modulator configured to apply a modulation at a given frequency to the wavelength or to the polarization of a laser beam emitted by a laser, to obtain a modulated laser beam;
a detection system comprising a detector configured to detect a position of the modulated laser beam after incidence on and redirection from the substrate;
a lock-in amplifier configured to receive an output from the detection system and, based upon the frequency of the modulation applied to the wavelength or the polarization of the laser beam, to measure a modulation of the detected position of the modulated laser beam; and
a processor configured to use the measured modulation of the detected position to determine a substrate height measurement error.

11. The substrate height measurement error determination system of claim 10, wherein the modulator and the lock-in amplifier are both part of a signal module.

12. The substrate height measurement error determination system of claim 11, wherein the lock-in amplifier automatically selects between a first harmonic, second harmonic, or other harmonic of the frequency of the modulation based upon amplitudes of those harmonics.

13. The substrate height measurement error determination system of claim 10, wherein the wavelength is modulated and the modulator is configured to modulate the wavelength of the laser beam by up to 1/100^{th} of the wavelength of the laser beam.

14. The substrate height measurement error determination system of claim 10, wherein the wavelength is modulated and the modulator is configured to modulate the wavelength of the laser beam by up to 100 pm.

15. A measurement system comprising the substrate height measurement error determination system according to claim 10, and a substrate height measurement system, wherein the processor is configured to use the determined substrate height measurement error to adjust a measured height of the substrate obtained using the substrate height measurement system.

16. The measurement system of claim 15, wherein the detection system comprises part of the substrate height measurement system.

17. A lithographic apparatus comprising the measurement system of claim 15.

18. The substrate height measurement error determination system of claim 10, wherein the height measurement error is an absolute value being determined with reference to known refractive indices of layers of the substrate.

19. The substrate height measurement error determination system of claim 10, wherein the height measurement error is a relative value being determined by comparison of the measured modulation of the detected position of the modulated laser beam with measured calibration modulations obtained using a different substrate having a layer structure which corresponds with the layer structure of the substrate being measured.

20. The substrate height measurement error determination system of claim 10, wherein the height measurement error is a relative value being determined by comparison between the measured modulation of the detected position of the modulated laser beam for different measured locations on the substrate.
